(19) United States
(12) Patent Application Publication
(10) Pub. No.: US 2008/0186691 A1
(43) Pub. Date: Aug. 7, 2008

(54) IMPLANTABLE MEDICAL DEVICE HOUSING REINFORCEMENT

(76) Inventors: John C. Mertz, Maple Grove, MN (US); Robert A. Youngman, Phoenix, AZ (US); Terry L. Sterrett, Cave Creek, AZ (US)

Correspondence Address: MEDTRONIC, INC., 710 MEDTRONIC PARKWAY NE, MINNEAPOLIS, MN, 55432-9924, US

(21) Appl. No.: 11/380,746

(22) Filed: Apr. 28, 2006

(51) Int. Cl. H05K 7/14; H05K 3/36

(52) U.S. Cl. 361/796; 29/830

(57) ABSTRACT

The main new features of the disclosure relate to the ability to add stiffness to a shield portion of an active implantable medical device (AIMD) without increasing the net displaced volume to the AIMD in application. A number of techniques for adding stiffness are disclosed, depicted and claimed herein; for example using a sheet or strip(s) of material. A sheet of material can be bonded to a portion of an AIMD housing where an internal component makes contact with and/or is otherwise supported by the housing. The sheet and/or rib can be adhered or welded, soldered, brazed, etc. The sheet or rib can couple to the interior and/or exterior of the housing. Also, preproduction preparation of bulk material used to fabricate the shields can include region(s) of increased cross section (thickness). Such bulk material can have regions of increased cross section (thickness) that correspond to production equipment for punching, shaping and/or trimming the bulk material into the desired AIMD housing.

### FIELD OF THE INVENTION

The present invention relates to active implantable medical devices (AIMDs) that include but are not limited to, at least one circuit board (e.g., a silicon-based-integrated circuit (IC) hybrid board also commonly known as a hybrid microelectronic module), one or more power sources (e.g., a chemical battery), and optionally high voltage capacitors and/or sensors of various types. These components are typically coupled to a major surface of a hermetic housing via mechanical means.

### BACKGROUND OF THE INVENTION

For a number of reasons manufacturers of AIMDs are continuously attempting to reduce the volume of devices they produce. One way to reduce device volume is to directly mount a circuit board to the interior of a housing for an AIMD. Unfortunately, due in part to the relatively thin material used to fabricate the housing, mechanical forces can cause the housing to exhibit unacceptable flexing and/or bending and potentially undermine the intended degree of mechanical stability critical to such compact device design. For example, a typical AIMD can have a 0.012″ titanium plate for the housing. At such thicknesses, this plate material exhibits substantial mechanical compliance, especially in large span applications (e.g., for implantable cardioverter-defibrillator devices, or ICDs, and for cardiac resynchronization therapy (CRT), defibrillator and pacing devices). Making the hermetic housings thicker would increase stiffness, but this also increases device volume. In particular, for AIMDs having a circuit board (hybrid microelectronic module) bonded to the inner surface(s) of the housing any mechanical deformation of the housing is transferred to the circuit board. If the plate material used to construct the housing were mechanically stiffer, less deformation of the circuit board and other components would occur, and thereby reduce the potential for damage to the circuit board and associated components, especially for AIMDs intended for long-term use.

### SUMMARY

The main new features of the invention relate to the ability to increase the stiffness of the shield without adding substantially to the net displaced volume of an active implantable medical device (AIMD). Increased stiffness of the shield will add mechanical robustness to an AIMD. It does not (necessarily) increase the net displaced volume of the device in such applications because many AIMDs enclose unoccupied internal volume over or under the enclosed components. The invention covers diverse ways for increasing shield stiffness. A first embodiment being wherein the reinforcement is selective (i.e. only in critical areas, like abutting a circuit board) using, for instance a rib, strip, and/or sheet of material (carbon fiber, titanium, or any other appropriately selected material) bonded to a portion of the housing where the circuit board(s) or other components make contact with the housing. Such a sheet can be bonded with an adhesive (e.g., an epoxy-based adhesive) or via other means (e.g., weld, solder, braze, etc.) to permanently connect a sheet of material to the interior or exterior major surfaces of the housing. The material could be comprised of any biocompatible material, if connected to the exterior of the AIMD (e.g., titanium, stainless steel, or any other biocompatible material). Another embodiment involves preproduction preparation of the bulk material used to fabricate the shields. For example, the bulk material is provided with regions of increased stiffness that correspond, or are physically keyed, to production equipment for punching, shaping and/or trimming the bulk material into the desired configuration of a housing with selectively located support features.

The shield stiffener aspects of the present invention thus provide extra stiffness in the areas where necessary, without adding net displaced volume where not necessary.

### BRIEF DESCRIPTION OF THE DRAWINGS

The drawings appended hereto are intended for those of skill in the art and are not drawn to scale but rather are provided to illustrate several embodiments of the invention. These embodiments are not intended to be limiting but rather illustrative of various other embodiments, all of which are intended to be covered by the claims hereof.

FIG. 1 is a diagrammatic representation of the process steps involved in an exemplary embodiment of a method according to the present invention.

FIG. 2 illustrates a drawing and forming apparatus and a view of a medical device housing half, manufactured in accordance with an embodiment of the present invention.

FIG. 3 is an elevational side view illustrating a housing having a thickened region and with the thickened region supporting one of more components for an AIMD.

FIG. 4 is an elevational side view illustrating a substrate having thickened regions and with portions of the thickened regions supporting one of more components for an AIMD.

FIG. 5 is an exploded perspective view of an AIMD and the components which are hermetically sealed by the formed device housing.

### DETAILED DESCRIPTION OF THE ILLUSTRATED EMBODIMENTS

In the following detailed description, references are made to illustrative embodiments for selectively reinforcing at least a portion of a housing for an active implantable medical device (AIMD), such as an implantable pulse generator, drug pump, and the like.

The present invention provides enhanced volumetric efficiency by enabling usage of very thin, stiff biocompatible materials to fabricate the housing or shield with operative components coupled directly to the thin flexible materials, among other advantages.

In accordance with an aspect of the present invention, methods and apparatus are provided for AIMDs that resist deformation where the operative components are coupled to a portion of a housing for the AIMD, thus decreasing the likelihood of damage to the device while providing maximum interior volume for the circuitry and thereby providing reduced net displaced device volume in the application.

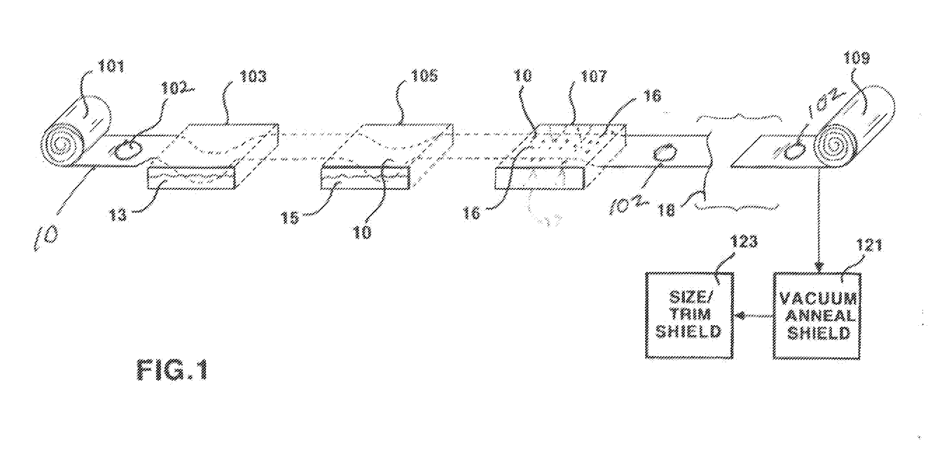

Referring now to FIG. 1, the steps for preparing a titanium substrate 10 in accordance with an embodiment of the present invention are diagrammatically illustrated. Generally, a coil of rolled bulk titanium (and derivative alloys) 101, which has been pre-rolled to a precise thickness dimension (e.g., about 0.014″ over a majority of its surface and a relatively thicker dimension over selective portions thereof 102) according to the invention. The bulk titanium material 101 is used generally in the manufacture of AIMD housings due to its high strength, ductility, fracture resistance, biocompatibility, and corrosion resistance and low specific gravity.

Turning now to an exemplary processing technique, at station 103 the titanium sheet 10 is rinsed in an alkaline fluid 13 prior to being submerged in an acidic solution 15 at station 105. The rinsing step at station 103 removes organic contaminates which reside on the surface of the titanium 10. This process (typically referred to as pickling) removes the oxide layer formed during an annealing step (not shown), and also cleans the substrate surface without dissolving away the surface layer produced during the unrolling step 101. Station 107 represents the next step of surface finishing (e.g., bead blasting) the titanium substrate 10 with metallic or other appropriate media 16 (e.g., stainless steel beads). As depicted and described, this involves blasting the titanium substrate 10 with a plurality of stainless steel beads 16 of a uniform size. In one embodiment, the stainless steel beads 16 are selected to have a diameter of 0.002″-0.004″ in diameter. Bead blasting with the stainless steel beads tends to leave a surface finish which has a satin appearance to the human eye. It is noteworthy that the bead blasting of the titanium substrate 10 and the 0.002″-0.004″ diameter stainless steel beads 16 leaves no stainless steel beads (or stainless steel residue) embedded in the titanium substrate 10 subsequent to the bead blasting step at station 107. Subsequent to the bead blasting step 107 the titanium substrate 10, which has been processed, is cut from the coil of rolled titanium 101 and is recoiled, hence a finished roll of titanium 109 is ready to be formed into device shields for a wide variety of AIMDs.

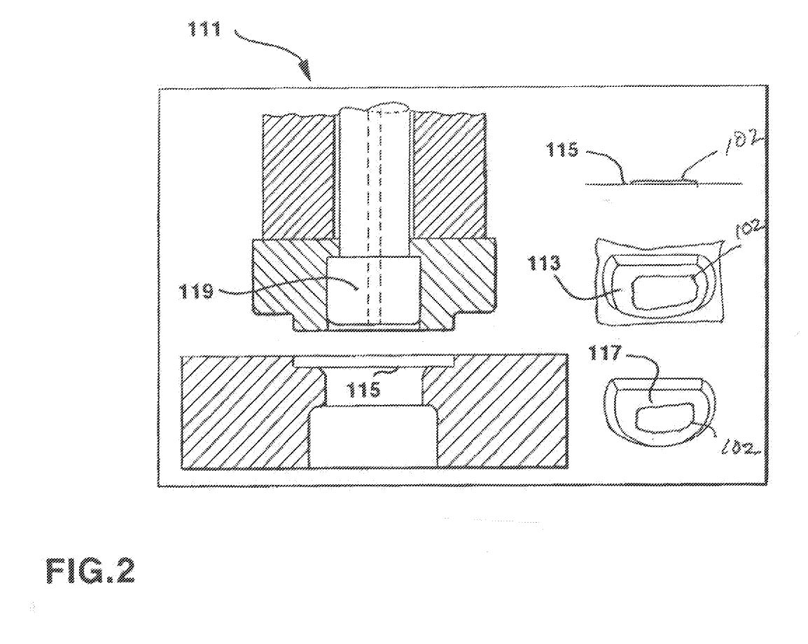

Turning now to FIG. 2, a procedure for drawing and forming a shield 117 for an AIMD is performed in accordance with conventional methods 111 with the exception that a region of larger cross section (thickness) 102 is located in a selected major planar area or areas. One embodiment of a device shield 117 is formed by a drawing and forming press 111 by first starting with a blank of processed titanium 115, cut from a coil of titanium sheet, processed as described above. Next, the drawing punch 119 forces the blank holder through the cylindrical opening in the die. In this way, a half housing is formed from the flat blank 115, as indicated by 115, 113, and 117, which show the blank 115, the half-drawn housing 113, and a finished device housing 117 (all including the region larger cross section (thickness)) after trimming for use as an enclosure for an AIMD. Because shield 117 has been drawn and formed from substrate material 10 which has already undergone pickling 105 and bead blasting 107, it is no longer necessary to perform these same process steps on the completed device shield 117. However, overall cosmetic appearance on a completed AIMD device shield may occasionally be improved by performing a subsequent touch-up bead blasting step, for example with a metallic media (e.g., stainless steel beads 16).

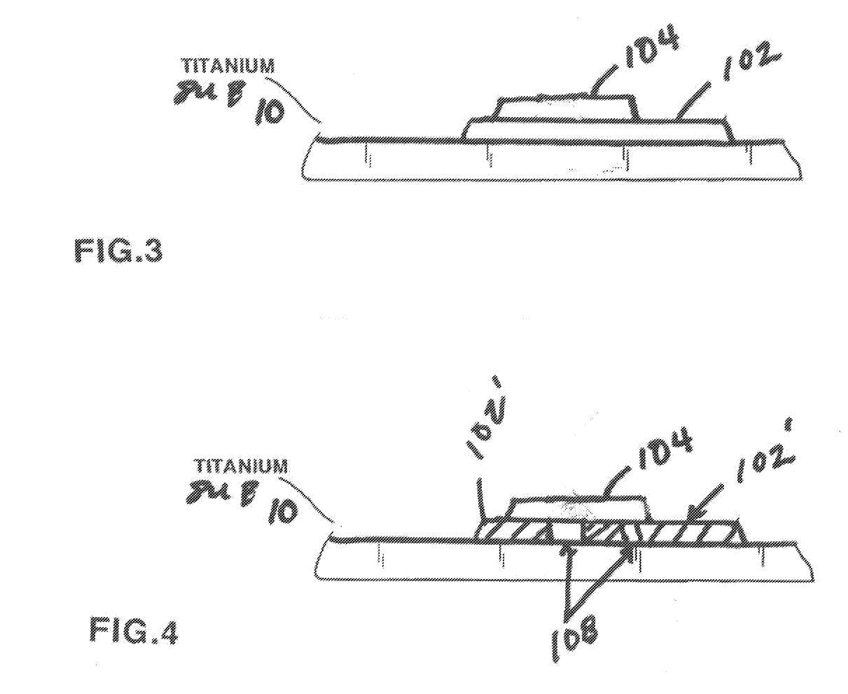

FIG. 3 depicts an elevational side view enlarged to illustrate one form of the invention wherein a portion of the titanium substrate 10 has a sheet of material 102 coupled thereto thus providing reinforcement to the substrate 10 while supporting internal components 104. As noted above, the sheet 102 can couple to the substrate 10 via any reasonable technique known in the art (e.g., adhesives, welding, soldering, brazing, electron-beam bonding, etc.) along discrete portions of an edge, along the entire area of sheet 102 or at other discrete locations.

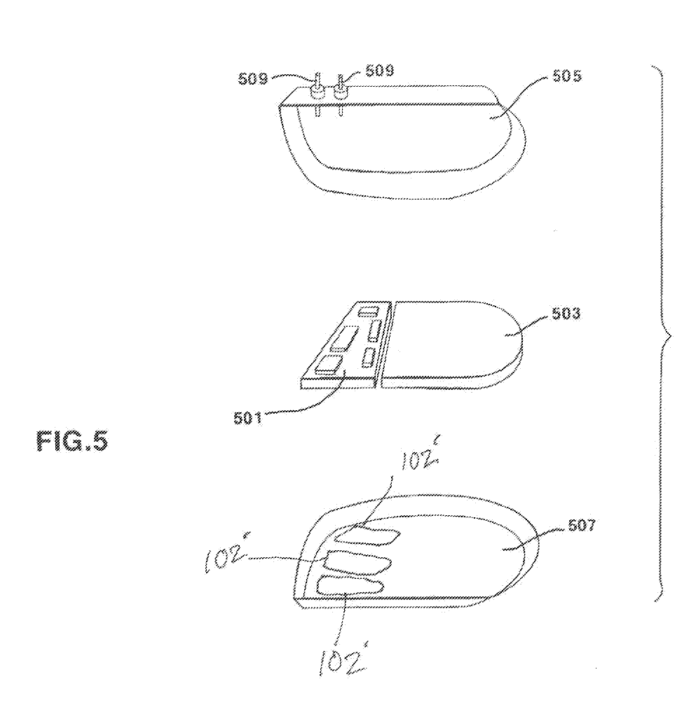

Now referring to FIG. 4, a series of discrete portions of a reinforcing material 102′ is depicted as providing the mechanical support for the internal components 104 of an AIMD according to the invention. The discrete portions of material 102′, can comprise any appropriately selected material (e.g., metal, resin-based compounds, composite materials, and the like). The location of the portions of material 102′ can correspond to the locations that some or all of the components 104 abut the substrate 10, but they can also be located in other locations that lend structure integrity to the housing 117 used to complete an hermetic enclosure for an AIMD.

The final step in the fabrication process typically involves sizing and trimming the housing half 113 (at station 123). This can be performed in accordance with conventional methods. Generally, the sizing and trimming at station 123 is the final process step which takes place on the AIMD housing 117 prior to manufacture and hermetic enclosure of the completed device, including operative circuitry, within the device shields 117. Sizing and trimming affects subsequent medical device manufacturing processes not shown, e.g., machining and welding operations. For example, accurate sizing and trimming 123 contributes to elimination of touch-up bead blasting discussed hereinbefore and simplifies the welding or other bonding technique used to coupled two housing halves 117 together to form the hermetic enclosure.

Turning to FIG. 5, a finished AIMD (e.g. a cardiac pacemaker, drug pump, neurostimulator, implantable cardioverter-defibrillator, deep brain stimulator, etc.) is formed by mounting one or more feedthroughs 509 to one or more of the housing halves 505,507, enclosing the internal components 501 (e.g. pulse generator circuitry) and the power source (battery cell) 503, optionally one or more capacitors for an ICD (not shown), and optionally one or more sensors (not shown) within the housing halves 505,507, coupling the power source 503 to the circuitry, coupling the circuitry to the feedthroughs 509 and subsequently welding the housing halves together along their edges to form a substantially hermetic enclosure. A molded plastic connector block assembly (not illustrated) containing electrical connectors for attachment to the feedthroughs 509 is typically installed thereafter.

While the invention has been described above in connection with the particular embodiments and examples, one skilled in the art will appreciate that the invention is not necessarily so limited. For example, while as illustrated, both housing halves 505 and 507 are illustrated as three dimensional, formed members, an enclosure may be produced using only one three-dimensional, formed housing member and one planar, unformed housing member. It will thus be understood that numerous other embodiments, examples, uses, modifications of, and departures from the teachings disclosed may be made, without departing from the scope of the present invention as claimed herein.

In addition, it will be understood that specifically described structures, functions and operations set forth in the above-referenced patents can be practiced in conjunction with the present invention, but they are not essential to its practice. It is therefore to be understood, that within the scope of the appended claims, the invention may be practiced otherwise than as specifically described without actually departing from the spirit and scope of the present invention.

1. A method of manufacturing an active implantable medical device (AIMD), comprising:
providing a substrate of a biocompatible material;
reinforcing the substrate over at least one location, wherein said at least one location comprises a relatively stiffer region;
supporting internal components over at least a part of the relatively stiffer region; and
joining said substrate and an additional substrate to one another to form an enclosure containing said components, wherein the enclosure comprises a hermetic housing for an active implantable medical device (AIMD).

2. A method according to claim 1 wherein said substrate comprises a titanium material.

3. A method according to claim 1 further comprising vacuum annealing said substrate.

4. A method according to claim 3 further comprising sizing and trimming said vacuum annealed substrate.

5. A method according to claim 1, wherein reinforcing comprises bonding at least two rib members to form the relatively stiffer region.

6. A method according to claim 1, wherein reinforcing comprises bonding a substantially flat plate member within the relatively stiffer region.

7. A method according to claim 1, wherein reinforcing comprises fabricating more than one relatively stiffer region during one of a metal stamping step and a metal rolling step.

8. A method according to claim 1, wherein joining comprises continuously welding the substrate and the additional substrate.

9. A method according to claim 8, wherein continuously welding comprises continuously laser welding.

10. An apparatus, comprising:
means for providing a substrate of a biocompatible material;
means for reinforcing the substrate over at least one location, wherein said at least one location comprises a relatively stiffer location;
means for supporting at least one electronic component abutting at least a part of the relatively stiffer location; and
means for joining said substrate and an additional substrate to one another to form an enclosure containing said components, wherein said enclosure comprises a hermetic housing for an active implantable medical device (AIMD).

11. An apparatus according to claim 10, wherein said substrate comprises a titanium material.

12. An apparatus according to claim 10, further comprising means for vacuum annealing said substrate.

13. An apparatus according to claim 12, further comprising means for sizing and trimming said vacuum annealed substrate.

14. An apparatus according to claim 10, wherein reinforcing comprises bonding at least two rib members to form the relatively stiffer location.

15. An apparatus according to claim 10, wherein reinforcing comprises bonding a substantially flat plate member to form the relatively stiffer location.

16. An apparatus according to claim 10, wherein said AIMD comprises one of: an implantable drug delivery device, an implantable neurostimulation device, an implantable gastric stimulator.

17. An apparatus according to claim 10, wherein said AIMD comprises an implantable cardioverter-defibrillator.

18. An apparatus according to claim 10, wherein said AIMD comprises an implantable fluid delivery device.

19. An apparatus according to claim 10, wherein said AIMD comprises an implantable pulse generator.

20. An apparatus according to claim 10, wherein said relatively stiffer location comprises both a plate member and at least one rib member.
